(19) United States
(12) Patent Application Publication
(10) Pub. No.: US 2014/0174801 A1
(43) Pub. Date: Jun. 26, 2014

(54) CONDUCTIVE MATERIAL AND PROCESS

(71) Applicant: HENKEL IP & HOLDING GMBH, Duesseldorf (DE)

(72) Inventors: Bin Wei, Franklin Park, NJ (US); Allison Yue Xiao, Belle Mead, NJ (US)

(73) Assignee: HENKEL IP & HOLDING GMBH, Duesseldorf (DE)

(21) Appl. No.: 14/195,040

(22) Filed: Mar. 3, 2014

Related U.S. Application Data
(63) Continuation of application No. PCT/US2012/053775, filed on Sep. 5, 2012.
(60) Provisional application No. 61/531,328, filed on Sep. 6, 2011.

(51) Int. Cl. H05K 1/09; C09D 11/00; H05K 3/10

(52) U.S. Cl. CPC H05K 1/097; H05K 3/10; C09D 11/52
USPC 174/257; 427/98.4; 252/514

(57) ABSTRACT

A conductive ink comprises nanosilver particles, and adhesion promoters, in which no binders, such as polymers or resins, are used in the compositions. In one embodiment the adhesion promoters are oxydianiline and 4,4-(1,3-phenylenedioxy)dianiline.

### CROSS-REFERENCE TO RELATED APPLICATION

This application is a continuation of International Patent Application No. PCT/US2012/053775 filed Sep. 5, 2012, which claims the benefit of U.S. Provisional Application Ser. No. 61/531,328 filed Sep. 6, 2011, the contents of both are incorporated herein by reference.

### FIELD OF THE INVENTION

This invention relates to conductive ink compositions that contain nano size metal particles and adhesion promoters. In particular, the compositions contain nanosilver. These compositions are suitable for use in the formation of fine circuits for electronic devices.

### BACKGROUND OF THE INVENTION

Silver has the lowest electrical resistivity among single metals, and silver oxide is also conductive, unlike the oxides of other metals. Consequently, micron scale silver flakes are widely used with resins and polymers to prepare conductive inks and adhesives for applications within the electronics industry. Neighboring flakes need to be in contact with each other to form a conductive network throughout the matrix of resins and polymers. However, each physical contact between the flakes creates a contact resistance, and the numerous contact points contribute to a 25 to 30 times higher overall resistance of the ink or adhesive than would be obtained with bulk silver.

To overcome the contact resistance, silver flakes can be sintered into a continuous network. Sintering, however, requires temperatures of 850° C. or higher. Most substrates, other than ceramic or metal, cannot tolerate temperatures in this range. This limits the conductivity obtainable from micron scale silver flakes when high temperature cannot be accommodated.

In such a scenario, nanosilver provides an alternative. Nanosilver is defined here as silver particles, flakes, rods, or wires that have at least one dimension that is measured as 100 nanometers (nm) or less. Dissimilar to micro sized silver flake, nanosilver is able to both sinter at temperatures as low as 100° C. and provide sufficient conductivity for electronic end uses.

The drawback to nanosilver is that a sintered network of nanosilver has very weak adhesion to the substrates of application. To overcome the weak adhesion, organic binding agents, typically polymers and/or resins, are added to the nanosilver to increase the adhesion and the mechanical strength. The presence of binding agents, however, can hinder the sintering of the nanosilver, making it difficult to obtain both high conductivity and adhesion suitable to the end use.

Thus, there is a need for conductive inks containing nanosilver that can be sintered without interference from binders in the composition, and yet provide sufficient adhesion to substrates.

### SUMMARY OF THE INVENTION

This invention is a conductive ink comprising nanosilver particles, and adhesion promoters, in the absence of polymeric or resin binders.

In one embodiment the adhesion promoters are aromatic or aliphatic amines. In another embodiment the amines are selected from oxydianiline and 4,4-(1,3-phenylenedioxy)dianiline.

The amines are present at a level within the range of 0.1 to 10% by weight of the nanosilver particles.

In another embodiment, this invention is a conductive trace prepared by depositing a conductive ink comprising nanosilver particles and adhesion promoters onto a substrate and heating the conductive ink to sinter the silver. Trace is used herein to mean a conductive pattern, for example, as will be used for circuitry in an electronic device.

### DETAILED DESCRIPTION OF THE INVENTION

The nanosilver particles used to make the conductive ink can be synthesized by various methods known in the art, for example, those described in US Patent Application Publications 2006/0090599 and 2005/0116203, or they can be purchased from commercial suppliers.

Whether synthesized in-house or purchased, nanosilver particles are usually coated with one or more compounds chosen to prevent agglomeration of the particles. The compounds, referred to as capping agents, are known in the art and in general are compounds containing a nitrogen, oxygen or sulfur atom. These compounds are adsorbed or bonded to the surface of the nanoparticles and are chosen so that they burn off during sintering.

The nanosilvers are generally used within the size range of 1 to 100 nanometers (nm).

In order to form the conductive ink of this invention, nanosilvers, usually supplied coated with capping agent, are added to adhesion promoters and mixed until the silver is well dispersed. In preferred embodiments, the adhesion promoters used in the conductive ink of this invention are small molecules (not polymers), such as, alkyldiamines, alkyltriamines, aromatic diamines, and aromatic triamines, or their combination.

In one embodiment, the amines are aromatic amines, such as, 1,4-phenylenediamine, 1,1′-binaphthyl-2,2′-diamine, 4,4′-(9-fluorenylidene)dianiline, biphenyldiamine, 4,4′-(1,1′-biphenyl-4,4′-diyldioxy)dianiline, 4,4′-(4,4′-isopropylidenediphenyl-1,1′-diyldioxy)dianiline, 2,2′-(hexamethylenedioxy)dianiline, oxydianiline, 2,2′-(pentamethylenedioxy)dianiline, 3,3′-(penta-methylenedioxy)dianiline, 4,4-(1,3-phenylenedioxy)dianiline, 4,4′-(tetramethylenedioxy)dianiline, and 4,4′-(trimethylenedioxy)dianiline.

In a further embodiment the amines are aromatic amines selected from oxydianiline and 4,4-(1,3-phenylene-dioxy)dianiline.

In another embodiment, the amines are alkylamines, such as, ethylenediamine, hexamethylenediamine, diethylenetriamine, and bis(hexamethylene)triamine.

The adhesion promoters are present in an amount within the range of 0.1 to 10% by weight of the nanosilver.

In some embodiments the adhesion promoters are provided in a solvent and the nanosilver is added to the solution of adhesion promoters and solvent. In some embodiments a minor amount of dipropylene glycol methyl ether, about 0.1 to 10% by weight or less, can be added to the solution to assist in dissolving the aromatic amine.

The loading of silver nanoparticles into the solvent can be within any range that will allow a stable dispersion, although it is preferable to have as high a loading as possible so that less solvent need be used and burned off during subsequent sintering. In one embodiment, the loading of silver nanoparticles into the solvent is within the range of 5% to 70% by weight of silver in solvent.

Suitable solvents or combinations of solvents for the nanosilver are any that can efficiently disperse the nanosilver. Exemplary solvents or combinations of solvents are selected from the group consisting of propylene carbonate, ethylene glycol, diethylene glycol, triethylene glycol, ethylene glycol diacetate, dipropylene glycol methyl ether, methylerythritol and pentaerythritol. In one embodiment, the solvent is ethylene glycol. These solvents can also act as reducing agents, thereby hindering the oxidation of the silver. In some embodiments, water may also be used as a solvent or a co-solvent with the above mentioned organic solvents.

Additional surfactant and wetting agents, if and as needed, may be added in effective amounts as determined by the practitioner.

The mixing can be accomplished by any effective means or combination of effective means, such as with high speed mixing, shearing, sonication, or cavitation. The mixing should be for an amount of time sufficient to make a stable dispersion, usually a period from a few minutes to three or four hours. A dispersion is considered stable if the nanoparticles remain dispersed, that is, do not fall out of suspension, for at least a few days. In practice, the dispersions of this invention remain stable for several months. If the particles fall out of suspension earlier, a longer period of mixing time, such as one or two more hours, can be used to improve the stability. An example of a mixing protocol is given later in this specification, and other mixing protocols can be determined by the practitioner without undue experimentation.

The mixture of the nanosilver and aromatic amine adhesion promoters in a stable dispersion is the resultant conductive ink. To form a conductive trace, the conductive ink is deposited in a desired pattern on a predetermined substrate and heated to remove the coating of surfactant on the nanosilver particles, evaporate off the solvent, and sinter the nanosilver. As will be understood, the substrate should be chosen to survive the sintering temperature.

Nanosilvers sinter at lower temperatures than are possible for conventional silver flake, which are in the micrometer size range. The sintering temperature for nanosilver is in a range from 100° C. to 200° C.; in another embodiment, in a range from 120° C. to 170° C.; in a further embodiment, in a range from 140° C. to 160° C.; in another embodiment, in a range from 145° C. to 155° C.; and generally at 150° C., plus or minus one or two degrees.

The sintering temperature is applied for a period of time ranging from one minute to one hour, depending on the particle size and surface capping agents. The larger the particle size and the more dense the surface capping agents, the longer the sinter time that will be required. The sintering temperature and sintering time may vary from ink to ink and from application to application, but in general the sintering temperature will be lower by at least about 50° C. than the sintering temperature needed for inks of similar compositions containing micro scale silver flakes.

After sintering occurs, the resultant conductive trace consists essentially of nanosilver and adhesion promoters.

In other embodiments, nanosized metal particles other than silver, suitable for use in forming electrical components in electronic devices, can be similarly utilized. Such nanosized metal particles are selected from the group consisting of copper, gold, platinum, nickel, zinc, and bismuth, and mixtures of these, and from mixtures of conductive metals that form solders and alloys.

### EXAMPLE

Composition A, containing oxydianiline, and Composition B, containing 4,4-(1,3-phenyldioxy)dianiline were formulated independently into two samples of conductive ink. Comparison Composition C was formulated without amine adhesion promoters. The compositions of the conductive inks by weight in grams were the following:

| | Compo- | Compo- | Compo- |
|---|---|---|---|
| | sition A | sition B | sition C |
| Nanosilver (S2-30W) | 29.60 | 30.83 | 37.80 |
| Oxydianiline | 0.58 | 0.00 | 0.00 |
| 4,4-(1,3-Phenyldioxy)dianiline | 0.00 | 0.58 | 0.00 |
| Glycerol | 7.91 | 8.01 | 4.88 |
| Ethylene glycol | 58.54 | 58.48 | 44.94 |
| Dipropylene glycol methyl ether | 0.98 | 0.92 | 0.00 |
| Water | 1.76 | 0.44 | 1.57 |
| Surfactant (OROTAN 731A) | 0.63 | 0.65 | 0.77 |
| Surfactant (SYNPERONIC 91/6) | 0.00 | 0.07 | 0.04 |

Nanosilver supplied as product S2-30W was purchased from NanoDynamics; surfactant supplied as product OROTAN 731A was purchased from Rohm and Haas; surfactant supplied as product SYNPERONIC 91/6 was purchased from Croda.

Composition A was initiated by dissolving adhesion promoter oxydianiline in ethylene glycol and dipropylene glycol methyl ether. Composition B was initiated by dissolving adhesion promoter 4,4-(1,3-phenyldioxy)dianiline in ethylene glycol and dipropylene glycol methyl ether. The nanosilver, OROTAN surfactant, and glycerol were added to each of these adhesion promoter solutions and the solutions mixed at 3000 rpm for 30 seconds until the silver was well dispersed in each solution.

Composition C was prepared by mixing the nanosilver, OROTAN surfactant, and glycerol in ethylene glycol at 3000 rpm for 30 seconds until the silver was well dispersed.

All three dispersions were transferred to glass jars and sonicated for one hour. Then the SYNPERONIC surfactant was added to each and the dispersion sonicated for another 30 minutes. The resultant dispersions were filtered through a 0.45 filter to provide a smooth liquid solution. The solutions were spin-coated at 2500 rpm onto polyimide film substrates and the substrate and solutions heated on a hot plate at 150° C. for 30 minutes. The polyimide substrates were not damaged by the heating.

When examined by SEM (scanning electron micrography), the nanosilver displayed sintering into a continuous network. Sintering was determined to have occurred when the nanoparticles melted together; initially these melts were observed as dumbbell shapes, and later as a continuous and contiguous network of the sintered particles.

Resistance was measured on four samples for each composition using a four-point probe. The films from all three compositions demonstrated resistivity values ranging from 1.6×10⁻⁵ Ω·cm to 2.2×10⁻⁵ Ω·cm.

The films from compositions A and B had adhesion on the plastic substrates deemed strong by passing a tape test in which SCOTCH brand adhesive tape was hand pressed onto the top of the conductive film on the polyimide substrate and then peeled off. The films remained intact, indicating adhesion sufficient for conductive traces in electronic device end uses.

In comparison, the films made from composition C without the amine adhesion promoters had very weak adhesion to the substrate. These films were easily touched off by finger tip.

The data show that compositions can be prepared only from nanosilver particles with amine adhesion promoters and have both commercially acceptable adhesion and conductivity.

1. A conductive ink comprising nanosilver particles and adhesion promoters, in the absence of polymeric and resin binders.

2. The conductive ink according to claim 1 in which the adhesion promoters are aromatic or alkyl diamines or triamines.

3. The conductive ink according to claim 2 in which the amines are aromatic amines selected from the group consisting of 1,4-phenylenediamine, 1,1′-binaphthyl-2,2′-diamine, 4,4′-(9-fluorenylidene)dianiline, biphenyldiamine, 4,4′-(1,1′-biphenyl-4,4′-diyldioxy)dianiline, 4,4′-(4,4′-iso-propylidenediphenyl-1,1′-diyldioxy)dianiline, 2,2′-(hexamethylenedioxy)dianiline, oxydianiline, 2,2′-(pentamethylene-dioxy)dianiline, 3,3′-(pentamethylenedioxy)dianiline, 4,4-(1,3-phenylene-dioxy)dianiline, 4,4′-(tetramethylenedioxy)dianiline, and 4,4′-(trimethylenedioxy)dianiline.

4. The conductive ink according to claim 3 in which the amines are selected from the group consisting of oxydianiline and 4,4-(1,3-phenylenedioxy)dianiline.

5. The conductive ink according to claim 2 in which the amines are alkyl amines selected from the group consisting of ethylenediamine, hexamethylenediamine, diethylenetriamine, and bis(hexamethylene)triamine.

6. The conductive ink according to claim 1 in which the adhesion promoters are present at a level within the range of 0.1 to 10% by weight of the nanosilver particles.

7. A conductive trace prepared by depositing a conductive ink onto a substrate and heating the ink to sinter the silver, the conductive ink comprising nanosilver particles and adhesion promoters.

8. The conductive trace according to claim 7 in which the adhesion promoters are present in an amount of 0.1 to 10% by weight of the nanosilver particles.

9. The conductive trace according to claim 7 in which the adhesion promoters are selected from oxydianiline and 4,4-(1,3-phenylenedioxy)dianiline.
